(19) United States
(12) Patent Application Publication
(10) Pub. No.: US 2010/0307571 A1
(43) Pub. Date: Dec. 9, 2010

(54) Using energy relay dyes to increase light absorption in dye-sensitized solar cells

(76) Inventors: Brian E. Hardin, Stanford, CA (US); Michael D. McGehee, Palo Alto, CA (US)

Correspondence Address: LUMEN PATENT FIRM, 350 Cambridge Avenue, Suite 100, PALO ALTO, CA, 94306, US

(21) Appl. No.: 12/801,000

(22) Filed: May 26, 2010

Related U.S. Application Data
(60) Provisional application No. 61/217,758, filed on Jun. 3, 2009.

(51) Int. Cl. H01L 31/00

(52) U.S. Cl. 136/252

(57) ABSTRACT

Improved efficiency for dye-sensitized solar cells is provided using a combination of dyes that have distinct roles—a sensitizing dye and an energy relay dye. The sensitizing dye is disposed on the surface of a photo-electrode, and is capable of absorbing incident radiation and of transferring charge at the photo-electrode surface. The energy relay dye is disposed in the electrolyte of the solar cell. The energy relay dye is capable of absorbing incident radiation and is capable of non-radiative energy transfer to the sensitizing dye. The energy relay dye need not be capable of direct charge transfer at the photo-electrode surface. We have found that the presence of such an energy relay dye can significantly increase solar cell efficiency compared to conventional dye-sensitized solar cell approaches having the dye (or dyes) all adsorbed to the photo-electrode surface. In an experiment, a 26% increase in power conversion efficiency was obtained when using an energy relay dye (PTCDI) with an organic sensitizing dye (TT1).

### CROSS REFERENCE TO RELATED APPLICATIONS

This application claims the benefit of U.S. provisional patent application 61/217,758, filed on Jun. 3, 2009, entitled “Using Energy Relay Dyes to Increase Light Absorption in Dye-Sensitized Solar Cells”, and hereby incorporated by reference in its entirety.

### GOVERNMENT SPONSORSHIP

This invention was made with Government support under contract number N00014-08-1-1163 awarded by the Office of Naval Research. The Government has certain rights in this invention.

### FIELD OF THE INVENTION

This invention relates to dye-sensitized solar cells.

### BACKGROUND

Dye-sensitized solar cells (DSCs) are based on light harvesting by a sensitizing dye attached to a wide band gap semiconductor. DSCs including abundant, non-toxic materials offer an inexpensive route to develop highly efficient photovoltaic cells. State-of-the-art DSCs, which absorb light from 350-700 nm, have validated power conversion efficiencies of over 11%. A key to improving the efficiency of DSCs is to increase their spectral absorption range. In order to reach power conversion efficiencies of 15% using an I₂⁻/I₃⁻ redox couple, DSCs must absorb ˜80% of the solar spectrum from 350-900 nm. Light absorption in dye-sensitized solar cells is determined by the molar extinction coefficient of the sensitizing dye, the surface coverage of the dye (dye molecules/nm²), and the total surface area of the oxide film. Films typically include TiO₂ nanoparticles to enhance the surface area; 10-μm-thick films can have surface areas 1000× greater than that of a flat junction. Sensitizing dyes generally pack tightly on the TiO₂ surface with a density of 0.5-1 dye molecule/nm². The sensitizing dye has traditionally been made from ruthenium based complexes (e.g. N719 and 2907) that have fairly broad absorption spectrum (Δλ˜350 nm) but low molar extinction coefficients (5,000-20,000 M⁻¹ cm⁻¹). Organic dyes have recently been developed with substantially higher molar extinction coefficients (50,000-200,000 M⁻¹ cm⁻¹) but narrow spectral bandwidths (Δλ˜250 nm). As a general rule, dyes that absorb strongly do not typically exhibit broad absorption.

Co-sensitization of titania by dyes with complimentary absorption spectra has been demonstrated to enhance light absorption and broaden the spectral response of organic DSCs. Representative examples of this state of the art include US 2005/0166958, US 2009/0211638, and an article by Cid et al., entitled “Molecular Cosensitization for Efficient Panchromatic Dye-Sensitized Solar Cells” (Angewandte Chemie Int. Ed. 2007, 46, 8358-8362), all of which are incorporated by reference in their entirety. However, the limited number of sites on the titania surface to attach dye molecules places a constraint on the light absorption achievable by co-sensitization. Furthermore, co-sensitization requires that each dye adsorb strongly on the surface, transfer charge efficiently into the TiO₂, have slow recombination (i.e. in the millisecond time domain), and regenerate with the redox couple. Few dyes exist that are both excellent absorbers and possess the requisite energy levels and chemical anchoring groups to be good sensitizing dyes. Accordingly, it would be an advance in the art to provide dye-sensitized solar cells that alleviate these difficulties.

### SUMMARY

Improved efficiency for dye-sensitized solar cells is provided using a combination of dyes that have distinct roles—a sensitizing dye and an energy relay dye. The sensitizing dye is disposed on the surface of a photo-electrode (e.g., a porous TiO₂ structure), and is capable of absorbing incident radiation and of transferring charge at the photo-electrode surface. The energy relay dye is disposed in the electrolyte of the solar cell (i.e., it is not adsorbed to the photo-electrode surface like the sensitizing dye is). The energy relay dye is capable of absorbing incident radiation and is capable of non-radiative energy transfer to the sensitizing dye (e.g., by Förster resonant energy transfer (FRET)). The energy relay dye need not be capable of direct charge transfer at the photo-electrode surface. We have found that the presence of such an energy relay dye can significantly increase solar cell efficiency compared to conventional dye-sensitized solar cell approaches having the dye (or dyes) all adsorbed to the photo-electrode surface.

With this approach, there are two paths by which solar energy can contribute to solar cell photocurrent. The first path is the conventional direct path where radiation is absorbed by the sensitizing dye. The second path is an indirect path where radiation is absorbed by the energy relay dye, which can then non-radiatively transfer energy to the sensitizing dye. Both paths can contribute significantly to device efficiency. For example, the sensitizing dye can be designed to provide high absorption at relatively long wavelengths of the solar spectrum, while one or more energy relay dyes provide coverage of relatively short wavelengths of the solar spectrum.

### BRIEF DESCRIPTION OF THE DRAWINGS

FIG. 1a shows a dye-sensitized solar cell according to an embodiment of the invention.

FIG. 1b is an enlarged view of the example of FIG. 1a.

FIG. 2a shows absorption and emission spectra for dyes PTCDI and TT1.

FIGS. 2b and 2c show the chemical structures of dyes PTCDI and TT1, respectively.

FIG. 3 shows quenching of PTCDI by electrolyte species.

FIG. 4 shows modeling results for average excitation transfer efficiency.

FIG. 5 shows measured photocurrent density-voltage results.

FIG. 6a shows measured external quantum efficiency (EQE) results for a dye-sensitized solar cell.

FIG. 6b shows the measured effect of an energy relay dye on EQE.

### DETAILED DESCRIPTION

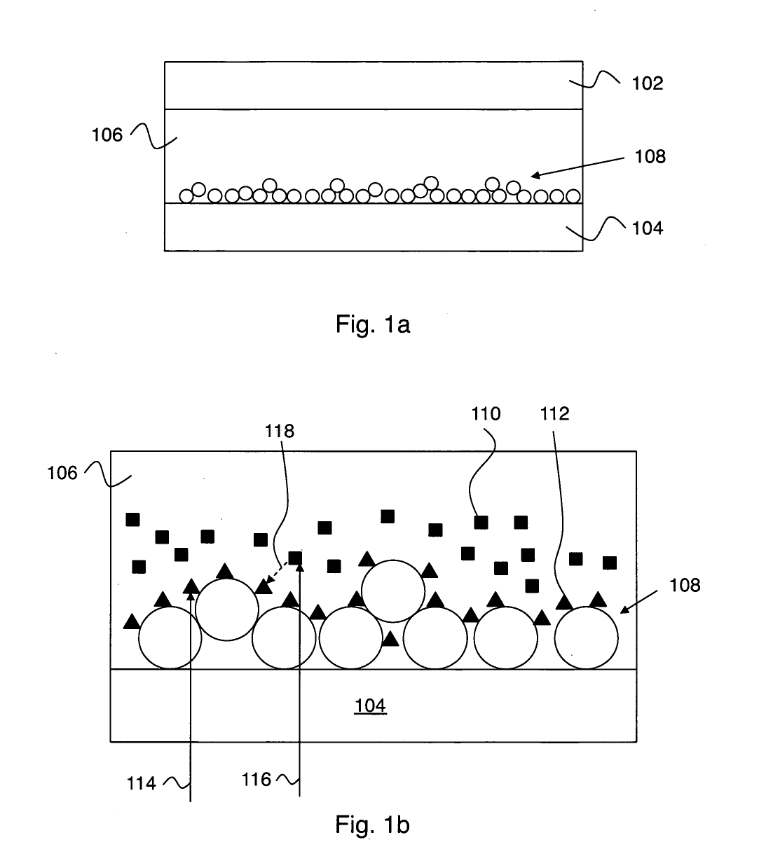

FIG. 1a shows a dye-sensitized solar cell according to an embodiment of the invention. FIG. 1b is an enlarged view of the example of FIG. 1a. In this example, a photo-electrode includes an electrode layer 104 and a nano-structured dye carrier layer 108. An electrolyte 106 is disposed between the photoelectrode and a back electrode 102. In the enlarged view of FIG. 1b, the sensitizing dye is shown as solid triangles (one of which is referenced as 112), and the energy relay dye is shown as solid squares (one of which is referenced as 110. Incident radiation (e.g., photons 114 and 116) can be absorbed by the sensitizing dye (photon 114) or by the energy relay dye (photon 116). After absorbing incident radiation, the energy relay dye is capable of non-radiative energy transfer (118) to the sensitizing dye.

Essentially any fast emitting dye (i.e., 10 ns or less radiative lifetime) that is soluble in the electrolyte solvent can be used as an energy relay dye. Another category of suitable energy relay dyes are dyes that are resistant to quenching by the electrolyte (e.g., dyes that are resistant to quenching by iodide in cases where the electrolyte is iodide/triiodide). For example, lanthanide dyes and cationic dyes that use iodide as a counter ion exhibit reduced quenching by iodide compared to most other dyes. For either of these categories, the energy relay dye preferably has a photoluminescent quantum efficiency of 10% or more in isolation, and preferably has a photoluminescent quantum efficiency of 3% or more when disposed in the electrolyte. One or more distinct dyes can be employed as energy relay dyes.

Suitable energy relay dyes include but are not limited to: perylene-3,4,9,10-tetracarboxylic diimide (PTCDI), derivatives of PTCDI, organic dyes, rhodamine dyes, cyanine dyes, 4-(Dicyanomethylene)-2-methyl-6-(4-dimethylaminostyryl)-4H-pyran (DCM), and laser dyes. Further information relating to suitable energy relay dyes is given in a textbook by Joseph R. Lakowicz entitled “Principles of Fluorescence Spectroscopy” (Springer, 2nd ed., 1999), hereby incorporated by reference in its entirety.

Sensitizing dyes are preferably highly absorbing (i.e., peak molar extinction coefficient of 25,000 M⁻¹ cm⁻¹ or more) to get a high enough FRET radius for efficient energy transfer. Suitable sensitizing dyes include but are not limited to: zinc phthalocyanine dyes and derivatives thereof, highly absorbing organic dyes, naphthalocyanines, cyanines, porphyrins, and squaraines. Further information relating to suitable sensitizing dyes is given in an article “Metal-Free Organic Dyes for Dye-Sensitized Solar Cells: From Structure: Property Relationships to Design Rules” by Peter Bauerle (Angewandte Chimie 2009), hereby incorporated by reference in its entirety. One or more distinct dyes can be employed as sensitizing dyes.

The electrolyte can be a solid electrolyte or a liquid electrolyte. In some cases, it is convenient to regard the electrolyte as including a conductive species disposed in an inert matrix. Suitable materials for the electrolyte matrix include, but are not limited to: volatile solvents, ionic liquids, gels, and solid organic hole conductors (e.g. spiro-OMeTAD). Suitable conductive species include, but are not limited to: iodide/triiodide ions; organic redox couples, such as 5-mercapto-1-methyltetrazole ion; and holes in solid state hole conductor electrolytes. Further information relating to organic redox couples is included in an article by Wang et al. entitled “An organic redox electrolyte to rival triiodide/iodine in dye-sensitized solar cells” (Nature Chemistry v2, 2010, pp 385-389), hereby incorporated by reference in its entirety. Further information relating to solid-state hole conductors and spiro-OMeTAD is given in an article by Ding et al., entitled “Pore-filling of Spiro-OMeTAD in Solid-State Dye Sensitized Solar Cells: Quantification, Mechanism and Consequences for Device Performance” (Advanced Functional Materials v19 2009), hereby incorporated by reference in its entirety.

It is preferable, but not required, for the dye carrier layer to have a nano-structured surface, as shown. Suitable nano-structured surfaces include but are not limited to surfaces of nano-particles, surfaces of nano-tubes, and/or surfaces of nano-rods. Preferably, the composition of the dye carrier layer includes TiO₂, SnO₂, ZnO or any mixture thereof.

The composition of electrode layer 104 and of back electrode 102 is not critical in practicing the invention. Electrode layer 104 is preferably transparent, in order to allow radiation to pass through with low loss. Suitable transparent electrode materials include, but are not limited to Fluorine-doped tin oxide (FTO). The back electrode can be either transparent or opaque. For example, Pt-coated FTO can be used as a back electrode.

### Experimental Results

The following is a description of an experiment relating to the use of an energy relay dye (ERD) in connection with dye-sensitized solar cells. All glassware was dried overnight in an oven or by flame prior to use. Reactions were carried out under nitrogen using standard Schlenk techniques. Reactions were monitored by thin layer chromatography using Whatman® 250 μm silica gel plates. Flash column chromatography was performed using Merck silica gel, 230-400 mesh. Solvents were removed with a rotary evaporator at aspirator pressure. All reagents were used as received from commercial suppliers without further purification. NMR spectra were recorded in CDCl₃ with a TMS standard using a Bruker AVB-400 spectrometer. ¹³C NMR was recorded at 100 MHz using ¹H decoupling. Mass spectrometry and elemental analysis data were recorded by staff members at the UC Berkeley mass spectrometry facility.

In this experiment we demonstrate that unattached, highly luminescent chromophores (e.g. PTCDI) inside a liquid electrolyte can absorb high energy photons and efficiently transfer the energy to an anchored near-IR sensitizing zinc phthalocyanine dye (e.g., TT1), increasing the absorption bandwidth of the DSC. FIG. 1b shows the two routes for charge generation incorporated in this system. In typical DSCs, light is absorbed by the sensitizing dye 112, which transfers an electron into the titania 108 and hole into the electrolyte 106. In the new approach, a second route for charge transfer is provided by the ERD, in addition to the conventional first route (absorption by the sensitizing dye). More specifically, the unattached energy relay dye 110 can be excited by higher energy (blue) photons (e.g., photon 116) and then undergo Förster energy transfer 118 to the sensitizing dye 112.

Using energy relay dyes has several important advantages. First, since the attached dye only has to absorb light over a smaller spectral region, it can be chosen to have a stronger and narrower absorption spectrum. Second, the sensitizing dye (SD) can be red shifted compared to the commonly used dyes since the energy relay dye can absorb higher energy photons. Furthermore, it is possible to place multiple ERDs with complimentary absorption spectra to tailor light absorption inside the device. Finally, the ERD does not need to be attached to the titania surface and with no additional processing steps can be mixed in very large concentrations inside the electrolyte. In summary, the addition of energy relay dyes into the electrolyte makes the overall absorption spectrum wider and stronger for the same film thickness. It is important to note that the ERDs need not participate in the charge transfer or collection process and thus do not require precise energy levels or specialized attachment groups. ERDs should be designed to be soluble in and not greatly quenched by the electrolyte. The energy relay dye concept is particularly applicable to solid-state DSCs that are currently restricted to being 2 μm thick and are not able to absorb all of the light even at the peak of the dyes absorption spectrum. Incorporating long range energy transfer into the solid-state DSC will require ERDs that avoid charge transfer into the hole transporter. The energy relay dye system is also extremely useful for nanostructured systems (e.g. TiO₂ nanotubes, ZnO nanorods) that have less available surface area and thus poorer light absorption.

Förster resonant energy transfer involves dipole-dipole coupling of two chromophores known as the donor and acceptor through an electric field. An excitation of the donor, or in our case the energy relay dye, can be transferred nonradiatively through the field to the acceptor, or sensitizing dye, if there is overlap between the emission spectrum of the donor and the absorption spectrum of the acceptor. Efficient energy transfer over 3-8 nm can be achieved with strong spectral overlap and high donor emission efficiencies, for an isotropic alignment between individual chromophores in solution. If, however, the single acceptor chromophore is replaced by a dense 2D array (i.e. sensitizing dyes tightly packed on the titania surface) FRET can become efficient well over 25 nm from the interface.

High FRET transfer rates (k_{FRET}) are important to quickly transfer the energy before the excited ERD nonradiatively decays. The FRET rate is dependent upon the Förster radius (Ro) between the energy relay dye and the sensitizing dye, the separation distance between the ERD and the SD/TiO₂ interface which is a function of pore size and geometry, and the natural fluorescence decay rate of the ERD, k₀=1/τ₀. The FRET radius (Ro), or the distance in which Förster energy transfer is 50% probable between individual chromophores, can be calculated using equation (1).

$${R}_{o}^{6} = \frac{9000 \cdot ln ( 10 ) {κ}^{2} {Q}_{D}}{128 \cdot {π}^{5} {n}^{4} {N}_{A}} \int {F}_{D} ( λ ) {ɛ}_{A} ( λ ) {λ}^{4} d λ \qquad ( 1 )$$

Here n is the index of refraction of the host medium (1.4-1.5 for the DSC electrolyte), K² is the orientational factor (⅔ for random orientation), N_{A} is Avogadro's number, Q_{D} is the photoluminescence efficiency, F_{D} is the emission profile of the donor, and ε(λ) is the molar extinction coefficient.

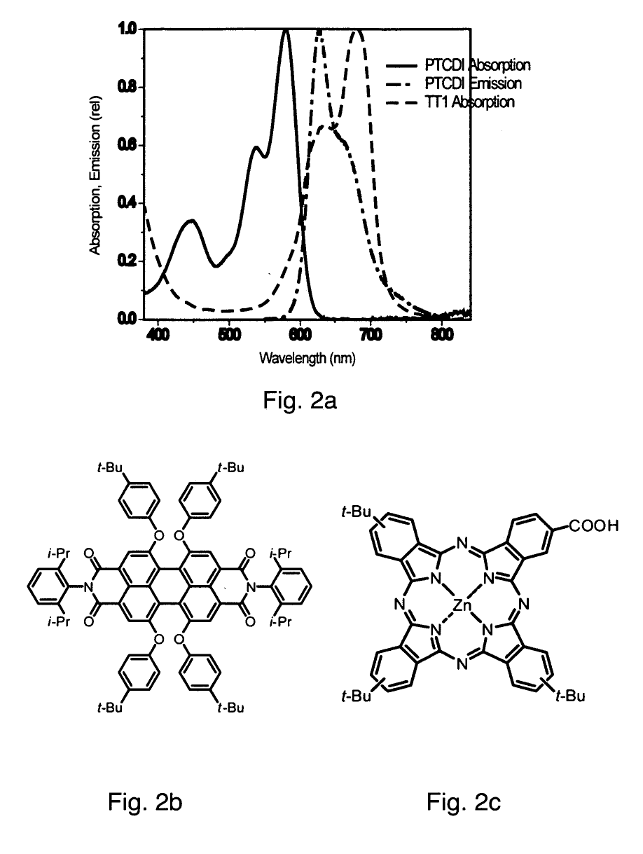

A previously reported derivative of perylene-3,4,9,10-tetracarboxylic diimide (PTCDI), shown in FIG. 2b, was synthesized for use as an ERD. Briefly, the synthesis was as follows. A solution of N,N′-di(2,6-diisopropylphenyl)-1,6,7,12-tetrachloroperylene-3,4,9,10-tetracarboxylic diimide (3.00 g, 3.54 mmol), 4-tert-butylphenol (2.66 g, 17.7 mmol), and potassium carbonate (2.92 g, 17.7 mmol) in anhydrous N-methylpyrrolidinone (50 mL) was stirred at 130° C. for 16 hours. The solution was rapidly poured into 1M HCl (200 mL) and the resulting precipitate was isolated by vacuum filtration and washed repeatedly with water. The precipitate was dissolved in chloroform and extracted twice with water. The chloroform layer was then dried over Na₂SO₄ and concentrated. Purification by flash column chromatography (eluent: 40%-55% dichloromethane in hexanes) yielded 1.55 g of red solid (34% yield). A portion of this product was further purified by recrystallization: 1.00 g of product was dissolved in dichloromethane (100 mL) and placed in a 1000 mL graduated cylinder. Methanol (200 mL) was carefully layered on top of the dichloromethane, and the two layers were allowed to mix slowly over 1 week. The resulting red crystals were isolated by filtration and dried under vacuum, yielding 740 mg of red product.

Characterization results for this PTCDI are as follows: m.p.>300° C. ¹H NMR (400 MHz, CDCl₃, δ): 8.29 (s, 4H), 7.42 (t, J=7.8 Hz, 2H), 7.22-7.28 (m, 12H), 6.87 (dt, J=8.8 and 2.5 Hz, 8H), 2.71 (m, J=6.8 Hz, 4H), 1.28 (s, 36H), 1.13 (d, J=6.8 Hz, 24H). ¹³C NMR (100 MHz, CDCl₃, δ): 163.55, 156.12, 152.99, 147.55, 145.82, 133.44, 130.88, 129.60, 126.88, 124.09, 122.89, 120.97, 120.45, 120.39, 119.41, 34.58 31.66, 29.28, 24.24. FTIR (film on NaCl): ν=2963, 2870, 1709, 1675, 1588, 1505, 1406, 1340, 1285, 1209, 1175 cm⁻¹. HRMS (FAB+, m/z): calcd for C₈₈H₉₁N₂O₈, 1303.6775; found, 1303.6786. Anal. calcd for C₈₈H₉₀N₂O: C, 81.07; H, 6.96; N, 2.15. found: C, 80.08; H, 6.97; N, 2.09.

PTCDI is a good energy relay dye candidate because of its extremely high photoluminescence efficiency (>90%), fast fluorescence lifetime (4.8 ns), excellent photo and air stability, and relatively strong absorption coefficient (50,000 M⁻¹ cm⁻¹ at 580 nm). Its bulky alkyl phenyl substituents were designed to reduce chromophore interactions between adjacent dye molecules in order to prevent aggregate formation and reduction of fluorescence.

A zinc phthalocyanine dye, 9(10),16(17),23(24)-Tri-tert-butyl-2-carboxy-5,28:14,19-diimino-7,12:21,26 dinitrilotetrabenzo[c,h,m,r]tetraazacycloeicosinator-(2⁻)-N²⁹,N³⁰,N³¹,N³² zinc (II) (TT1 for short), shown in FIG. 2c, was chosen as the sensitizing dye for its high molar extinction coefficient of 191,500 M⁻¹ cm⁻¹ centered at 680 nm. The synthesis of TT1 is described in the above referenced article by Cid et al. One would prefer a dye with a smaller energy gap, but such dyes are not readily available yet with the necessary anchoring groups. When attached to titania, the TT1 dye absorption broadens (as shown in FIG. 2a) and significantly overlaps the PL emission of the PTCDI. Given the absorption and emission profile of the TT1 and PTCDI respectively, the FRET radius is estimated to be 8.0 nm. Time resolved photoluminescence measurements on solutions with varying concentration of TT1 determined Ro to be 7.5-7.6 nm. Time resolved PL measurements were performed using a Time-Correlated Single Photon Counting (TCSPC) system from PicoQuant. Solutions were excited with a pulsed laser diode, (model LDH 485: 481 nm, 70 ps FWHM, 5 MHz) detected with a single photon avalanche diode (PDM 100CT SPAD) attached to a monochromator and processed by a PicoHarp 300 correlating system.

Once excited, the energy relay dye can transfer its energy to the sensitizing dye via FRET, emit a photon, or nonradiatively decay. Nonradiative decay in the DSC system is greatly increased due to the presence of triiodide in the electrolyte. Triiodide is a highly mobile ion that is known as a “perfect quencher”, meaning that collisions with the ERD have a near unity probability of quenching the excited state. Given the high concentrations of triiodide in the DSC electrolyte, the quenching rate of chromophores can be 20-2000 times greater than the natural decay rate. Collisional quenching of the PTCDI by triiodide is described by the Stern-Volmer equation (2),

$$\frac{{PL}_{0}}{PL} = \frac{{τ}_{0}}{τ} = 1 + {k}_{q} {τ}_{o} [ Q ] , \qquad ( 2 )$$

where PL₀ is the photoluminescence in the absence of a quencher, PL is the photoluminescence for given quencher concentration [Q], τ₀ is the natural fluorescence lifetime, τ is the fluorescence lifetime for a given [Q], and k_{q} is the bimolecular quenching constant typically around 10⁹-10¹⁰ M⁻¹ s⁻¹. Because the bimolecular constant and the electrolyte concentrations are relatively fixed, a short τ₀ is important for minimizing the fluorescence quenching. We determined the fluorescence lifetime of the PTCDI to be 4.8 ns.

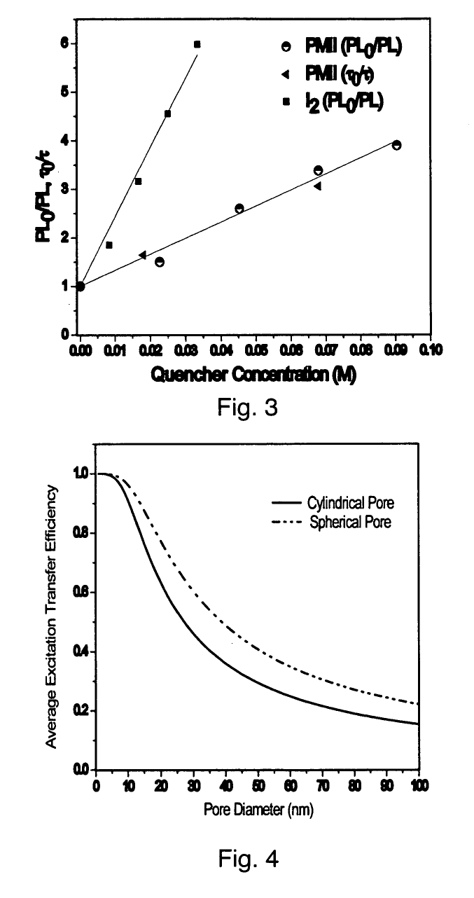

FIG. 3 shows that the fluorescence intensity and lifetime are both reduced with increasing concentrations of the 1-methyl-3-propyl imidazolium iodide (PMII) and I₂ species with a k_{q} of 3.17*10¹⁰ and 0.67*10¹⁰ M⁻¹ s⁻¹ respectively, indicating dynamic quenching. The PTCDI concentration was 1*10⁻⁴ M in gamma-butyrolactone. For the electrolyte used in this DSC experiment (0.6M PMII, 0.05M I₂) the nonradiative decay rate due to quenching (k_{QUENCH}) is calculated to be ˜30 times greater than the natural fluorescence decay rate (k_{QUENCH}=30 k₀).

The excitation transfer efficiency (ETE) is the probability that an excited energy relay dye will transfer its energy to a sensitizing dye. The ETE for a single relay dye molecule is dependent upon the rate of Förster energy transfer, k_{FRET}, relative to the combined rate of all decay mechanisms including the natural decay rate and quenching rate, equation (3).

$$ETE ( \vec{x} ) = \frac{{k}_{FRET} ( \vec{x} )}{{k}_{0} + {k}_{QUENCH} + {k}_{FRET} ( \vec{x} )} \qquad ( 3 )$$

The FRET rate is a function of the separation distance between the ERD molecule to nearby acceptor molecules. The rate of Förster energy transfer between isolated chromophores, known as point-to-point transfer, is given by k_{FRET}=k₀(Ro)⁶/r⁶, where r is the separation distance. When multiple acceptor molecules are present, the FRET rate is equal to the sum of the transfer rates to each of the acceptors. ERDs within the FRET Ro of the SD array will transfer their excitation with high efficiency, while ERDs in the middle of a large pore may be quenched before energy transfer occurs. We have developed a model that approximates the nanopores as either cylinders or spheres to calculate FRET rate profiles, k_{FRET}(\vec{x}) and excitation transfer efficiency profiles, ETE(\vec{x}), using equation (3) and assuming uniform sensitizing dye coverage over the pore walls. The morphology of the pores has important implications on ERD/SD array separation distance. Assuming a homogenous ERD concentration, the average separation distance between ERD and the closest SD/TiO₂ interface in a spherical pore is a quarter of the pore radius, while in a cylinder the average separation distance is one third of the pore radius. FIG. 4 shows how the average excitation transfer efficiency, E̅T̅E̅, depends upon the pore diameter for cylindrical and spherical pores using the parameters calculated for the PTCDI-TT1 DSC system. Modeling results are based on a Förster radius of 8.0 nm, conservative dye coverage estimate of 0.2 nm⁻², and a quenching rate of 30 k₀. Even though the excited ERD has a nonradiative decay half life of only 0.15 ns (4.8 ns/31) when placed in the electrolyte, it has an expected E̅T̅E̅ between 76-87% in a 15 nm pore.

The titania film included 20 nm particles to ensure close proximity of the energy relay dye to the sensitizing dye. The 20 nm TiO₂ particles produce pore diameters between 22-38 nm, a film porosity of 68% (without the addition of the dye), and a roughness factor of 97/μm. A 10-μm-thick layer of 20 nm particles and a 5-μm-thick layer of 400 nm scattering particles (CCIC, HPW-400) was formed via screen printing, sintered at 450° C., and subsequently treated in TiCl₄. The films were then dipped in a 1×10⁻⁵M solution of TT1 with 10 mM chenodeoxycholic acid for four hours and rinsed in acetonitrile.

Chloroform was chosen as the electrolyte solvent because PTCDI is significantly more soluble in it (>50 mM) compared to commonly used solvents such as acetonitrile (<2 mM) and gamma-butyrolactone (<2 mM). However, chloroform based electrolytes displayed lower internal quantum efficiency (70% vs. 80%) and lower power conversion efficiencies at higher light intensities. These issues are caused by the reduced I₃⁻ concentration, lower solubility of useful additives such as LiI and guanidinium rhodanide, and the lower dielectric constant of chloroform (ε=5) compared to acetonitrile (ε=36). The electrolyte contained 0.6M PMII, 0.05M I₂<0.04M tertbutyl pyridine, <0.01M LiI, and <0.02 guanidinium thiocyanate in chloroform. 13 mM of PTCDI was subsequently added before electrolyte filling of the DSC. The counter electrode in this experiment was platinum on FTO glass (TEC 15Ω/, 2.2 mm thick, Pilkington). Electrodes were sealed using a 25-μm-thick hot-melt film (Surlyn 1702, Dupont). A small hole was drilled in the counter electrode and electrolyte was filled using a vacuum pump. It should be noted that CHCl₃ has a low boiling and during electrolyte filling the concentration of PTCDI inside the DSC invariably changed. Higher molar concentrations of PTCDI in the electrolyte did not increase dye loading, but did result in clogging of the hole as the PTCDI electrolyte gelled quickly.

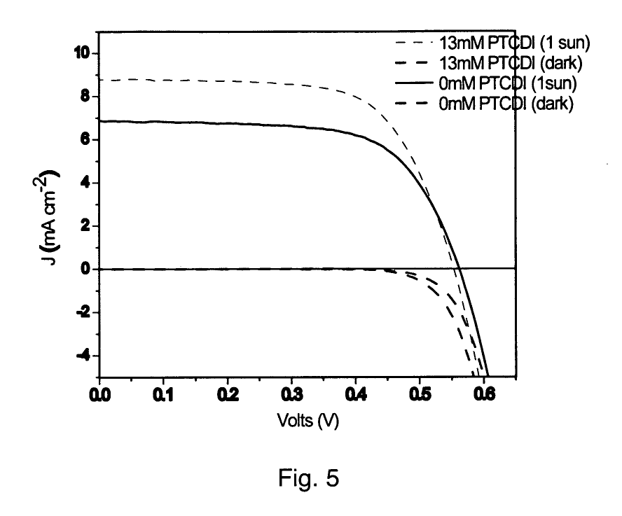

FIG. 5 shows the photocurrent density-voltage (J-V) characteristics of DSCs with and without the energy relay dye measured under AM 1.5G (100 mW cm⁻²) conditions. The power of the AM 1.5 solar simulator (100 mW cm⁻²) was calibrated using a reference silicon photodiode equipped with an infrared cutoff filter (KG-3, Schott) in order to reduce the mismatch between the simulated light and solar spectrum from 350-700 nm to less than 2%. The J-V curves were obtained by externally biasing the DSC and measuring the photocurrent using a Keithley 2400 digital source meter. All measurements were performed using a metal mask with an aperture of 0.159 cm² to reduce light scattering.

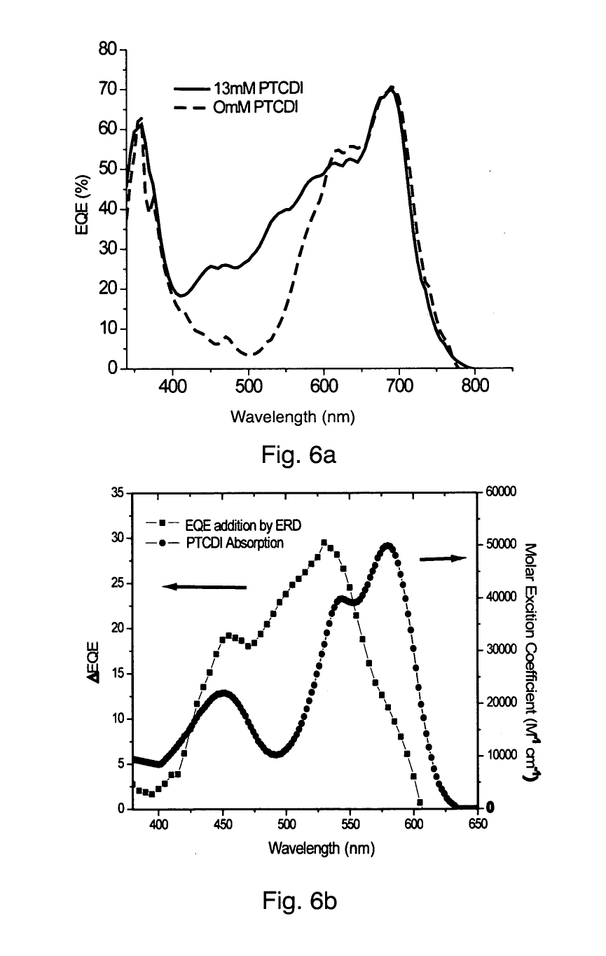

Devices containing no energy relay dye (0 mM PTCDI) had power conversion efficiencies (PCE) of 2.55% while devices with 13 mM of PTCDI had a PCE of 3.21%. The 26% increase in device performance is attributed to the increase in short-circuit photocurrent density (J_{SC}) caused by an increase in the EQE from 400-600 nm as shown in FIG. 6a, while the fill factor and Voc remained relatively unchanged. Devices made with PTCDI but without the sensitizing dye were found to have very low photocurrent (Jsc=<42 μA/cm² and PCE˜0.01%), demonstrating that energy transfer to the sensitizing dye is necessary for photocurrent generation by this ERD.

TABLE 1
PV characteristics

| | 13 mM PTCDI | 0 mM PTCDI | Change (%) |
|---|---|---|---|
| J_{sc} (mA cm⁻³) | 8.78 | 6.88 | 28 |
| V_{oc} (mV) | 553 | 562 | −1.60 |
| Fill factor | 0.66 | 0.65 | −1.50 |
| PCE (%) | 3.21 | 2.55 | 26 |

The EQE measurement light source was a 300 W xenon lamp (ILC Technology, USA), which was focused through a Gemini-180 double monochromator (Jobin Yvon Ltd). EQE measurements were performed at 1% sun using a metal mask with an aperture area of 0.159 cm². Integrating the EQE spectra of the ERD containing and control DSC result in slightly higher (˜10%) estimated J_{SC} at full sun than those measured in the devices. This is a result of charge transport limitations caused by the electrolyte at higher light intensities. Extrapolating device results from measurements taken at 10% sun to full sun are consistent with the estimated J_{SC} from the EQE results. The difference in the integrated EQE spectrum between the ERD containing and control devices is the same ratio as the differences in J_{SC} at full sun.

A lower bound for external quantum efficiency of the energy relay dye (EQE_{ERD}) can be calculated from the difference between the EQE of the device containing the ERD and the EQE of the control, ΔEQE, shown in FIG. 6b. The EQE enhancement has a peak of 29.5% at 530 nm, which is 8×greater than the control (0 mM PTCDI). The ΔEQE spectrum does not perfectly match the absorption of PTCDI because light scattering is greater at lower wavelengths increasing the optical pathway and at longer wavelengths (>550 nm) the ERD and SD compete for light absorption. The external quantum efficiency of the energy relay dye is equivalent to the product of the absorption efficiency of the dye, the average excitation transfer efficiency, E̅T̅E̅, and the internal quantum efficiency of the control device, equation (4).

EQE_{ERD}=η_{abs,ERD}· E̅T̅E̅·IQE (4)

A minimum bound for the average excitation transfer efficiency can be calculated by assuming that there is complete light absorption at the ΔEQE peak. Using the dye absorption profiles, this corresponds to η_{abs,ERD}=89.7% from PTCDI and 10.3% by TT1. If the IQE is assumed to be equal to the peak EQE (70%), a minimum average ETE of 47% is calculated.

Using the distribution of pore sizes in the DSC measured by the Brunauer, Emmett, and Teller (BET) method, the spectrally calculated Förster radius (8.0 nm), the SD surface coverage of 0.2 dye/nm² and the quenching rate calculated above from lifetime measurements (k_{QUENCH}=30 k₀) we simulate an average excitation transfer efficiency of 49% for the cylindrical pores and 63% for the spherical pores. This is consistent with the minimum possible excitation transfer efficiency observed from the EQE data.

It is possible to increase the average excitation transfer efficiency by reducing the average pore size inside of the titania film. The excitation transfer efficiency can be greater than 80% when using smaller nanoparticles (e.g. 14 nm) assuming a sensitizing dye surface concentration of the sensitizing dye is 0.5 dye/nm² and a spherical pore geometry. Initial results using 14 nm nanoparticles indicate >69% excitation transfer efficiency when using PTCDI with TT1; however, more rigorous analysis can be employed to determine the exact concentration of PTCDI inside the film and the porosity of the samples with the inclusion of the sensitizing dye. Incorporating PTCDI derivatives that are soluble in acetonitrile or gamma-butyrolactone into films that contain smaller pores should allow power conversion efficiencies exceeding 5.5% for the PTCDI/TT1 system. If multiple relay dyes are incorporated into the system which have complimentary absorption spectra, a power conversion efficiency >7% is possible.

Given the predicted E̅T̅E̅, development of DSCs with power conversion efficiencies greater than 15% is possible by using a series of ERDs that absorb light from 350-800 nm and an SD that absorbs from 800-1000 nm. The realization of extremely efficient DSCs will be aided by research and development of sensitizing dyes that can absorb strongly in the infrared. Future infrared sensitizing dyes will not be required to absorb as broadly and because the Förster radius is dependent on the emission/absorption overlap multiplied by the wavelength to the fourth power (λ⁴ in equation (1)) it may not need to absorb as strongly. However, the SD will need to have excellent charge injection properties. The potential difference required between HOMO (highest occupied molecular orbital) of the sensitizing dye and the Nernst potential of the electrolyte is about 300 meV for the iodide/triiodide redox couple and 100-200 meV for the solid state hole conductor to regenerate the dye. There are many available fluorophores including quantum dots currently used for biomedical imaging that have the potential to be used as ERDs and it may be possible to design ERDs that are minimally quenched by triiodide. Candidates for ERDs should be fast emitters (<100 ns) to reduce quenching by the triiodide and preferably have moderately high photoluminescence quantum efficiency (>20%).

1. A dye-sensitized solar cell comprising:
a photo-electrode having a surface;
a sensitizing dye disposed on said surface;
an electrolyte in contact with said photo-electrode and in contact with said sensitizing dye;
an energy relay dye disposed in said electrolyte;
wherein said sensitizing dye and said energy relay dye are both capable of absorbing incident optical radiation;
wherein said sensitizing dye is capable of charge transfer at said surface; and
wherein said energy relay dye is capable of non-radiative energy transfer to said sensitizing dye.

2. The solar cell of claim 1, wherein said electrolyte comprises a solid electrolyte or a liquid electrolyte.

3. The solar cell of claim 1, wherein said surface of said photo-electrode is a nano-structured surface.

4. The solar cell of claim 1, wherein said nano-structured surface comprises surfaces of nano-particles, surfaces of nano-tubes, and/or surfaces of nano-rods.

5. The solar cell of claim 1, wherein said electrolyte includes a matrix selected from the group consisting of: volatile solvents, ionic liquids, gels, and solid organic hole conductors.

6. The solar cell of claim 1, wherein said electrolyte includes a conductive species selected from the group consisting of: iodide/triiodide ions, organic redox couples, and holes in solid-state hole conductor electrolytes.

7. The solar cell of claim 1, wherein said photo-electrode includes an electrode layer adjacent to a dye carrier layer, wherein said dye carrier layer is in contact with said electrolyte, and wherein said dye carrier layer provides said surface at which said sensitizing dye is disposed.

8. The solar cell of claim 7, wherein said electrode layer is transparent.

9. The solar cell of claim 7, wherein said electrode layer includes a metallic foil.

10. The solar cell of claim 7, wherein said dye carrier layer comprises TiO₂, SnO₂ or ZnO.

11. The solar cell of claim 1, further comprising a back electrode, wherein said electrolyte is disposed between said photo-electrode and said back electrode, and wherein said back electrode is in contact with said electrolyte.

12. The solar cell of claim 1, wherein said sensitizing dye has a peak molar extinction coefficient of 25,000 M⁻¹ cm⁻¹ or more.

13. The solar cell of claim 1, wherein said energy relay dye has a radiative lifetime of 10 ns or less.

14. The solar cell of claim 1, wherein said energy relay dye has a photoluminescent quantum efficiency of 10% or more in isolation.

15. The solar cell of claim 1, wherein said energy relay dye has a photoluminescent quantum efficiency of 3% or more when disposed in said electrolyte.
